(19) United States
(12) Patent Application Publication
(10) Pub. No.: US 2018/0115316 A1
(43) Pub. Date: Apr. 26, 2018

(54) SELF-CORRECTION TECHNIQUES FOR CRYSTAL OSCILLATOR

(71) Applicant: QUALCOMM Incorporated, San Diego, CA (US)

(72) Inventors: Ankit MAHESHWARI, Hyderabad (IN); Akash KUMAR, Hyderabad (IN); Rimal PATEL, Hyderabad (IN)

(21) Appl. No.: 15/335,333

(22) Filed: Oct. 26, 2016

(51) Int. Cl. H03L 1/00; H03L 7/00; H03B 5/06; H03B 5/32; G01R 31/28

(52) U.S. Cl. CPC H03L 1/00; H03L 7/00; H03B 5/06; H04W 76/046; G01R 31/2849; H03B 2200/0082; H03B 5/32

(57) ABSTRACT

Techniques for calibrating a crystal oscillator of a wireless device are provided. A method according to these techniques includes operating a transmit path of the wireless device at a first carrier frequency, configuring a receive path of the wireless device to receive at a second carrier frequency, the second carrier frequency being offset from the first carrier frequency by a first frequency offset, transmitting a tone using the transmit path at a frequency that is offset from the first carrier frequency by a second frequency offset that is different than the first frequency offset, receiving a second tone via the receive path, and determining the oscillator error based on the second tone.

### BACKGROUND

Crystal oscillators, or XOs are used in many electronic devices to assist with timing information and other processes relying on a steady frequency. Many kinds of XO crystals have been used in electronic devices, where different calibration methods may be used to compensate for variable changes in the frequency output by the XO.

In mobile phone design, the frequency output of the crystal oscillator circuit is multiplied by a known factor in a frequency synthesizer circuit to obtain a desired channel frequency. Cellular standards pose a requirement for very high accuracy and stability of frequency synthesizer circuit and hence the need for crystal oscillator calibration and/or correction.

Some conventional solutions for addressing crystal oscillator accuracy requirements include factory calibration, field calibration, and GNSS assisted calibration. In factory calibration, a frequency-temperature curve can be determined for the crystal oscillator at the factory representing an expected change in frequency of the crystal oscillator when exposed to different temperatures. Temperature measurements can be taken by the device in which the crystal oscillator is deployed and a frequency offset can be determined using the frequency-temperature curve. Field calibration techniques using good system information can also be used to fine tune factory calibration data and to account for aging of the crystal oscillator and for environmental conditions, such as temperature, vibration, humidity, pressure, and/or other environmental conditions that may affect the ability of the crystal oscillator to maintain desired accuracy. Global Navigation Satellite System (GNSS) signals, such as that of the Global Positioning System (GPS), Galileo, and/or GLONASS, can also be used to obtain a position fix for the device in which the crystal oscillator is installed and to estimate the local oscillator error based on this information.

### SUMMARY

An example method for calibrating a crystal oscillator of a wireless device according to the disclosure includes operating a transmit path of the wireless device at a first carrier frequency; operating a receive path of the wireless device at a second carrier frequency, the second carrier frequency being offset from the first carrier frequency by a first frequency offset; transmitting a first tone via the transmit path at a third carrier frequency, wherein the third frequency being offset from the first carrier frequency by a second frequency offset and wherein the second frequency offset is different than the first frequency offset; receiving a second tone via the receive path; and determining the oscillator error based on the second received.

Implementations of such a method may include one or more of the following features. In one example, the method includes determining the oscillator error based on the second tone. In one example, the first frequency offset is 10 MHz and the second frequency offset is 11 MHz. In one example, the method includes determining the oscillator error includes determining a received frequency at which the second tone is received at the receive path, determining a frequency difference between the received frequency and an expected receive carrier frequency when the second tone is received at the receive path, and calculating the oscillator error based on the frequency difference. In one example, calculating the oscillator error based on the frequency difference includes dividing the frequency difference by 10. In one example, the method includes determining whether a threshold condition for determining the oscillator error has occurred. In one example, the method includes determining whether the threshold condition has been satisfied includes waking the wireless device from a power save mode (PSM), attempting to latch on to a network at a predetermined frequency using the receive path of the wireless device, and determining that the threshold condition has occurred responsive to being unable to latch onto the network at the predetermined frequency. In one example, the method includes determining whether the threshold condition has been satisfied includes obtaining a measurement of an environmental parameter using a sensor of the wireless device, determining whether the measurement exceeds a predetermined environmental threshold associated with the environmental parameter, and determining that the threshold condition has occurred responsive to the measurement exceeding the predetermined environmental threshold. In one example, the method includes determining whether the threshold condition has been satisfied include determining an age estimate for the crystal oscillator, determining whether the age estimate exceeds a predetermined aging threshold, and determining that the threshold condition has occurred responsive to the age estimate exceeding the predetermined aging threshold.

An example apparatus according to the disclosure includes an oscillator error determining unit. The oscillator error determining unit is configured to operate a transmit path of the wireless device at a first carrier frequency; operate a receive path of the wireless device at a second carrier frequency, the second carrier frequency being offset from the first carrier frequency by a first frequency offset; transmit a first tone via the transmit path at a third carrier frequency, wherein the third carrier frequency being offset from the first carrier frequency by a second frequency offset and wherein the second frequency offset is different than the first frequency offset; receive a second tone via the receive path; and determine the oscillator error based on the second tone.

Implementations of such an apparatus can include one or more of the following features. In one example, the apparatus further comprises a calibration unit calibrate the crystal oscillator based on the oscillator error. In one example, the first frequency offset is 10 MHz and the second frequency offset is 11 MHz. In one example, the oscillator error determining unit is configured to determine a received frequency at which the second tone is received at the receive path, determine a frequency difference between the received frequency and an expected receive carrier frequency when the second tone is received at the receive path, and calculate the oscillator error based on the frequency difference. In one example, the oscillator error determining unit is configured to calculate the oscillator error based on the frequency difference includes dividing the frequency difference by 10. In one example, the oscillator error determining unit is configured to determine whether a threshold condition for determining the oscillator error has occurred. In one example, the oscillator error determining unit is configured to wake the wireless device from a power save mode (PSM), attempt to latch on to a network at a predetermined frequency using the receive path of the wireless device, and determine that the threshold condition has occurred responsive to being unable to latch onto the network at the predetermined frequency. In one example, the oscillator error determining unit is configured to obtain a measurement of an environmental parameter using a sensor of the wireless device, determine whether the measurement exceeds a predetermined environmental threshold associated with the environmental parameter, and determine that the threshold condition has occurred responsive to the measurement exceeding the predetermined environmental threshold. In one example, the oscillator error determining unit is configured to determine an age estimate for the crystal oscillator, determine whether the age estimate exceeds a predetermined aging threshold, and determine that the threshold condition has occurred responsive to the age estimate exceeding the predetermined aging threshold.

An example apparatus according to the disclosure includes means for operating a transmit path of the wireless device at a first carrier frequency, means for operating a receive path of the wireless device at a second carrier frequency, the second carrier frequency being offset from the first carrier frequency by a first frequency offset, means for transmitting a first tone via the transmit path at a third carrier frequency, wherein the third carrier frequency being offset from the first carrier frequency by a second frequency offset and wherein the second frequency offset is different than the first frequency offset, means for receiving a second tone via the receive path, and means for determining an oscillator error of a crystal oscillator of the wireless device based on the second tone.

Implementations of such an apparatus can include one or more of the following features. In one example, the first frequency offset is 10 MHz and the second frequency offset is 11 MHz. In one example, the means for determining the oscillator error include means for determining a received frequency at which the second tone is received at the receive path, means for determining a frequency difference between the received frequency and an expected receive carrier frequency when the second tone is received at the receive path, and means for calculating the oscillator error based on the frequency difference. In one example, the apparatus includes means for determining whether a threshold condition for determining the oscillator error has occurred. In one example, the means for determining whether the threshold condition has been satisfied include means for waking the wireless device from a power save mode (PSM), means for attempting to latch on to a network at a predetermined frequency using the receive path of the wireless device, and means for determining that the threshold condition has occurred responsive to being unable to latch onto the network at the predetermined frequency. In one example, the means for determining whether the threshold condition has been satisfied includes means for obtaining a measurement of an environmental parameter using a sensor of the wireless device, means for determining whether the measurement exceeds a predetermined environmental threshold associated with the environmental parameter, and means for determining that the threshold condition has occurred responsive to the measurement exceeding the predetermined environmental threshold. In one example, the means for determining whether the threshold condition has been satisfied includes means for determining an age estimate for the crystal oscillator, means for determining whether the age estimate exceeds a predetermined aging threshold, and means for determining that the threshold condition has occurred responsive to the age estimate exceeding the predetermined aging threshold.

The non-transitory, computer-readable medium, having stored thereon computer-readable instructions for calibrating a crystal oscillator of a wireless computing device according to the disclosure includes instructions configured to cause the wireless computing device to operate a transmit path of the wireless device at a first carrier frequency; operate a receive path of the wireless device at a second carrier frequency, the second carrier frequency being offset from the first carrier frequency by a first frequency offset; transmit a first tone via the transmit path at a third carrier frequency, wherein the third carrier frequency being offset from the first carrier frequency by a second frequency offset and wherein the second frequency offset is different than the first frequency offset; receive the second tone via the receive path; and determine an oscillator error based on the second tone.

Implementations of such a non-transitory, computer-readable medium can include one or more of the following features. In one example, the first frequency offset is 10 MHz and the second frequency offset is 11 MHz. In one example, the instructions configured to cause the wireless computing device to determine the oscillator error include instructions configured to cause the wireless computing device to determine a received frequency at which the second tone is received at the receive path, determine a frequency difference between the received frequency and an expected receive carrier frequency when the second tone is received at the receive path, and calculate the oscillator error based on the frequency difference. Instructions configured to cause the wireless computing device to determine whether a threshold condition for determining the oscillator error has occurred. In one example, the instructions configured to cause the wireless computing device to determine whether the threshold condition has been satisfied include instructions configured to cause the wireless computing device to wake the wireless computing device from a power save mode (PSM), attempt to latch on to a network at a predetermined frequency using the receive path of the wireless computing device, and determine that the threshold condition has occurred responsive to being unable to latch onto the network at the predetermined frequency. In one example, the instructions configured to cause the wireless computing device to determine whether the threshold condition has been satisfied include instructions configured to cause the wireless computing device to obtain a measurement of an environmental parameter using a sensor of the wireless computing device, determine whether the measurement exceeds a predetermined environmental threshold associated with the environmental parameter, and determine that the threshold condition has occurred responsive to the measurement exceeding the predetermined environmental threshold. In one example, the instructions configured to cause the wireless computing device to determine whether the threshold condition has been satisfied further comprise instructions configured to cause the wireless computing device to determine an age estimate for the crystal oscillator, determine whether the age estimate exceeds a predetermined aging threshold, and determine that the threshold condition has occurred responsive to the age estimate exceeding the predetermined aging threshold.

### BRIEF DESCRIPTION OF THE DRAWINGS

FIG. 1 is a functional block diagram of an example computer system illustrating the techniques disclosed herein.

FIG. 2 is a functional block diagram of an example computer system that can be used to implement the computer system illustrated in FIG. 1.

FIG. 3 is an illustration of an example process for calibrating a crystal oscillator of a wireless device according to the techniques disclosed herein.

FIG. 4 is an illustration of an example process for determining an oscillator error according to the techniques disclosed herein.

FIG. 5 is an illustration of an example process for determining an oscillator error according to the techniques disclosed herein.

FIG. 6 is an illustration of an example process for determining whether a threshold condition for determining an oscillator error has occurred according to the techniques disclosed herein.

FIG. 7 is an illustration of an example process for determining whether a threshold condition for determining an oscillator error has occurred according to the techniques disclosed herein.

FIG. 8 is an illustration of an example process for determining whether a threshold condition for determining an oscillator error has occurred according to the techniques disclosed herein.

FIG. 9 is an illustration of an example process for determining an oscillator error has occurred according to the techniques disclosed herein.

### DETAILED DESCRIPTION

Technique for calibrating a crystal oscillator of a wireless device are provided. The techniques disclosed herein can be used to calibrate the crystal oscillator of a wireless device. These techniques can be used to offset the effects of crystal aging and environmental factors, such as temperature, vibration, humidity, and pressure, and/or other factors on the crystal oscillator of a wireless device. For example, the wireless devices may be used in harsh environments, such as mines, where significant variations in temperature, vibration, humidity, and pressure may occur, which would require frequent crystal oscillator corrections. The techniques disclosed herein may be implemented in a mobile wireless device, such as wearable computing device, a smartphone, a table computer system or other computing device. The wireless device can be an Internet of Things (IoT) or enhanced Machine Type Communication (eMTC) device where the wireless device may be used in a remote location and may have an extended life cycle of 10 years or more. IoT and eMTC devices may not support GNSS or network-assisted techniques for performing field calibrations on the crystal oscillator. Furthermore, the IoT and eMTC devices may be located indoors or in another location where GNSS signals are blocked. Another challenge for maintaining oscillator accuracy in IoT, eMTC, and other such wireless computing devices is that these devices may enter into a Power Save Mode (PSM) in which the device operates in a state that minimizes energy consumption by switching off the transmit and/or receive capabilities of the wireless device while the device is operating in the PSM. The device may remain in the PSM for extended periods of time, and thus, cannot rely on network signals or other external sources to help maintain the accuracy of the oscillator. For example, some IoT and eMTC specifications indicate that such a device may remain in the PSM for more than 12 days. However, specific device implementations and protocols may vary how long the device may remain in the PSM. The conventional approach of using GNSS signals may not be available and the use of a recent “good” value is unavailable where the wireless device has been in the PSM for an extended period of time. Furthermore, the device may be moved to a new location while in the PSM mode and may have difficulty latching onto a new base station due to uncorrected frequency errors that have accumulated in the oscillator. Furthermore, such wireless computing devices may be used in remote locations where a camping failure due to frequency errors caused by crystal oscillator inaccuracy may render the device unusable and potentially unrecoverable.

Some current wireless techniques use a single resource block of approximately 200 kHz, and in this resource block may be further narrowed to 180 kHz. An error of approximately 10 PPM or 20 kHz at 2 GHz frequency band can result in a loss of services as the wireless device will not be able to successfully send an acknowledgement (ACK) to the desired channel frequency. The preceding examples source block size and frequencies are intended to illustrate the concepts for the techniques disclosed herein, and the techniques disclosed herein are not limited to these particular examples.

The techniques disclosed herein can be used by a wireless device to self-correct frequency errors caused by crystal oscillator inaccuracy, which can help facilitate the wireless device successfully latching onto a suitable base station/cell of a wireless network. The techniques disclosed here use the receive chain or feedback receive chain of the wireless device to capture a signal transmitted by the device and process this signal to calculate a frequency error for the crystal oscillator (also referred to herein as an oscillator error). The phase-locked loops (PLLs) of the transmit and receive chains can be tuned to a different frequency so that the error introduced by the crystal oscillator drift or crystal oscillator inaccuracy will be different for the transmit and receive chains. This difference can be used to estimate the frequency error of the crystal oscillator which can be used to compensate for the frequency error. The wireless device can be configured to perform the techniques disclosed herein upon waking from the PSM or can configured to perform these techniques responsive to one or more threshold conditions being met. Examples of such threshold conditions are discussed in detail below with regard to the various example implementations provided herein.

The techniques for calibrating a crystal oscillator of a wireless device disclosed herein can be run at various times. These techniques can be run during a factory test mode, during an initial startup or setup of the wireless device, during a power-up process of the device, in response to a command issued to the wireless device to perform the calibration techniques, after a time threshold has occurred, based on a non-timed threshold condition being satisfied (i.e., an interference measurement, signal strength measurement, an expected time drift, etc.) or any combination thereof. The techniques disclosed herein can also be initiated based on various threshold conditions discussed in the example implementations discussed herein.

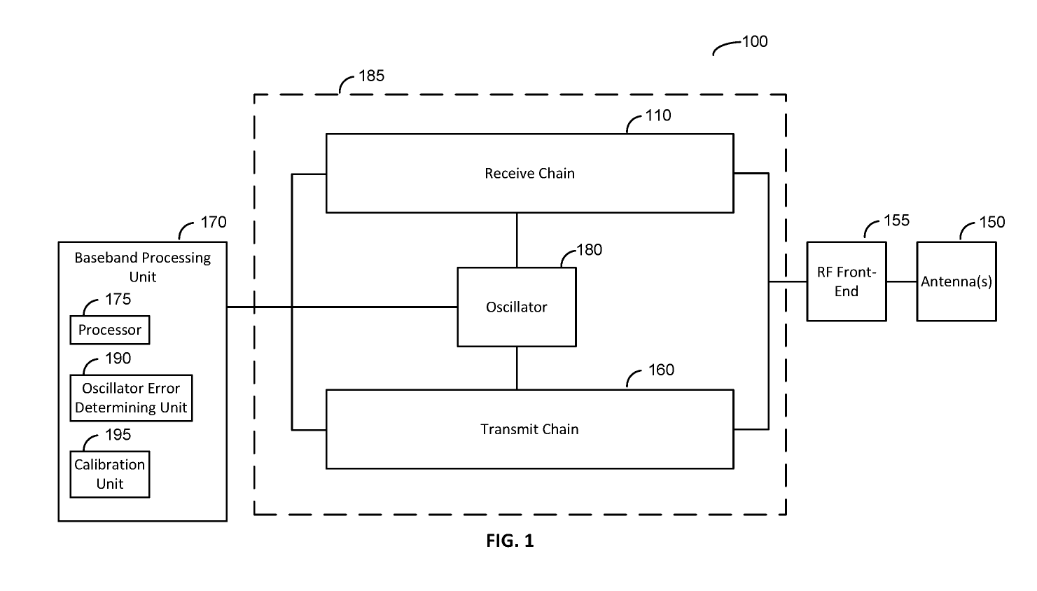

FIG. 1 is a functional block diagram of an example wireless computing device 100 illustrating the techniques disclosed herein. FIG. 1 illustrates components of the wireless computing device 100 that can be used to transmit and receive signals. Other components of the wireless computing device 100 have been omitted for clarity. The wireless computing device 100 can include a baseband processing unit 170, a transceiver 185, an RF front-end 155, and one or more antennas 150. The transceiver 185 can include a receive chain 110, and transmit chain 160, and an oscillator 180.

The transceiver 185 include components for transmitting and receiving wireless signals. The transceiver 185 can be used to transmit data to and receive data from other wireless devices. The transceiver 185 illustrated in FIG. 1 includes a single receive chain and a single transmit chain, but other implementations of the wireless computing device 100 can include more than one receive chain, such as the receive chain 110, which may be configured to receive wireless signals on different frequencies and/or more than one transmit chain configured to transmit wireless signals on different frequencies.

The oscillator 180 can comprise a crystal oscillator configured to generate an electrical signal output that has a precise frequency. The signal output by the oscillator 180 can be used by both the transmit chain 160 and the receive chain 110 of the transceiver 185 for frequency synthesis. The receive chain 110 can be configured to use the signal output by the oscillator 180 to down-convert wireless signals received by the one or more antennas 150 to a frequency that can be processed by the baseband processing unit 170. The transmit chain 160 can be configured to use the signal output by the oscillator 180 to up-convert the output from the baseband processing unit 170 prior to transmitting a signal via the one or more antennas 150. The receive chain 110 can include a phase-locked loop that can use the signal output by the oscillator 180 to down-convert wireless signals received by the one or more antennas 150. The transmit chain 160 can include a phase-locked loop that can use the signal output by the oscillator 180 to up-convert wireless signals to be transmitted by the one or more antennas 150.

The RF front-end 155 can include one or more filters, such as bandpass filters and/or one or more amplifiers for amplifying signals to be transmitted and/or signals received by the one or more antennas 150.

The baseband processing unit 170 can include a processor 175, an oscillator error determining unit 190, and calibration unit 195. The baseband processing unit 170 can be configured to perform various radio control functions for the wireless computing device 100. For example, the baseband processing unit 170 can be configured to perform signal generation, modulation/de-modulation, encoding/decoding of signals. The baseband processing unit 170 can include a processor 175 for performing various computations related to the signal processing tasks performed by the baseband processing unit 170. In some implementations, the baseband processing unit 170 can be implemented as a separate processing unit from the CPU of the wireless computing device 100. In other implementations, the functionality of the baseband processing unit 170 can be implemented by the CPU of wireless computing device 100.

The processor 175 can include one or more microprocessors, microcontrollers, and/or digital signal processors that provide processing functions, as well as other calculation and control functionality. The processor 210 can be coupled to storage media (e.g., memory) for storing data and software instructions for executing programmed functionality within the wireless computing device 100. The memory can be on-board the processor 175 (e.g., within the same IC package), and/or the memory can be external memory to the processor and functionally coupled over a data bus.

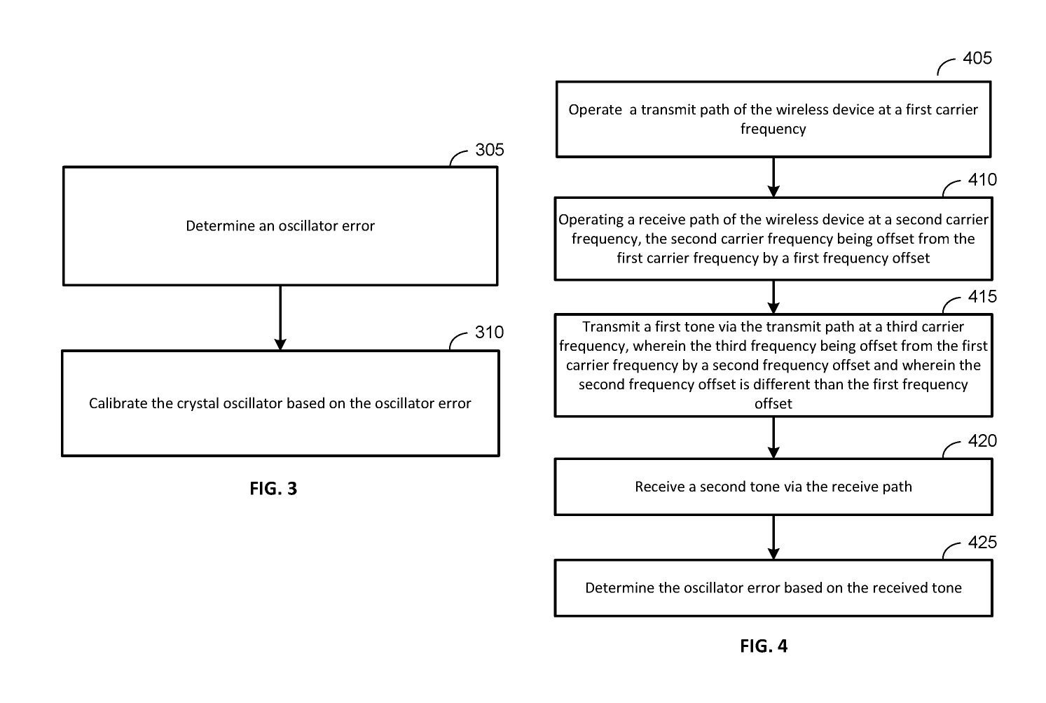

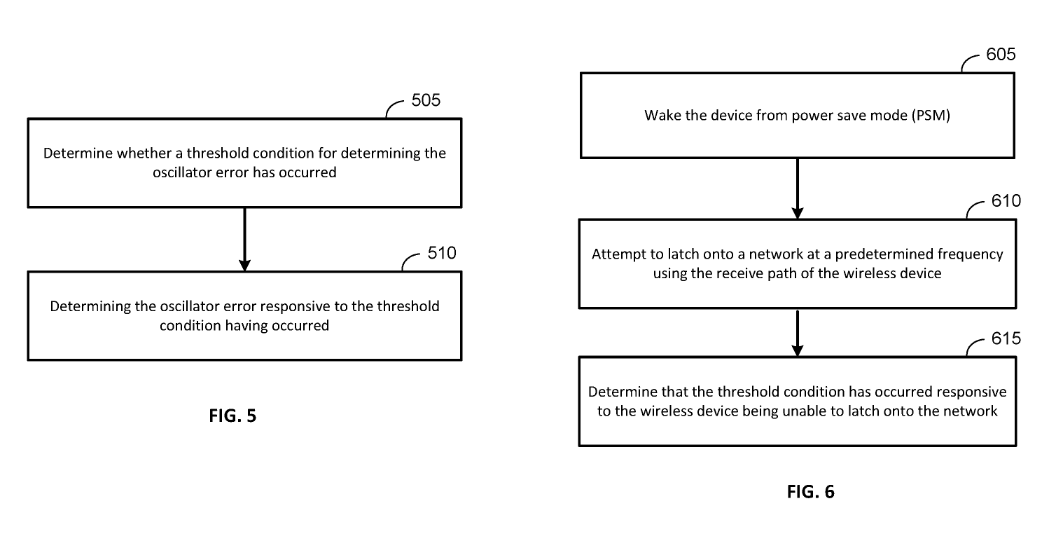

The oscillator error determining unit 190 can be configured to determine an oscillator error for the oscillator 180 using the various techniques disclosed herein, such as the example processes illustrated in FIGS. 3-9. The oscillator error determining unit 190 can also be configured to condition the determining of the oscillator error on the occurrence of one or more threshold conditions. Examples of such conditions are discussed with regard to FIGS. 5-8. The oscillator error determining unit 190 can be configured to provide the oscillator error to the calibration unit 195.

The oscillator error determining unit 190 can be configured to use the following technique to determine the oscillator error of the oscillator 180 of the wireless computing device 100. The oscillator error determining unit 190 can be configured to configure the transmit chain 160 and the receive chain 110 of the wireless computing device 100 to operate at predefined carrier frequencies. For example, the transmit carrier frequency of the transmit chain 160 can be set to X MHz, where X represents a frequency within a predetermined frequency within a frequency range in which the transmit chain 160 of the wireless computing device 100 is capable of transmitting, and the receive carrier frequency of the receive chain 110 can be set to X+Y MHz, where Y represents a predetermined frequency within the frequency range in which the receive chain 110 is capable of receiving. Y represents a first frequency offset that represents a difference between the transmit carrier frequency and receive carrier frequency. In an example to illustrate this concept, assume that Y equals 10 MHz, but the value of Y is not limited to this specific frequency offset value. The oscillator error determining unit 190 can be configured to configure the transmit chain 160 to transmit a first tone at 11 MHz on the transmit carrier frequency. The 11 MHz value is selected in this example because this frequency is offset from the transmit carrier frequency by a second frequency offset that is different than the first frequency offset. The oscillator error determining unit 190 can be configured to operate the receive chain 110 in a feedback mode so that a second tone can be received by the receive chain 110 responsive to the first tone being transmitted by the transmit chain 160. The frequency of the second tone should be offset from the transmit carrier frequency by a different frequency offset than the receiver carrier frequency. The carrier frequencies of the transmit and receive chains are tuned to different frequencies so that the error introduced by the oscillator drift will be different for the send and receive chains, and the delta between these two errors can be used to estimate the frequency error.

The oscillator error determining unit 190 can be configured to down-convert the received signal, which can be performed by oscillator error determining unit 190 or other components of the baseband processing unit 170. The expected receive carrier frequency when the second tone is received at the receive path expected to be at a 1 MHz frequency offset relative to the receive carrier frequency since the receive carrier frequency has been shifted by 10 MHz relative to the transmit carrier frequency. However, due to the inherent error in the oscillator frequency, which is expected to change linearly with a change in the carrier frequency, the frequency error seen by the receive chain 110 will be different than the frequency error experienced by the transmit chain 160. Accordingly, the second tone received by the receive chain 110 will not be exactly at 1 MHz if there is a oscillator error. Assuming for this example, that the second tone received at the receive chain 110 is shifted by Z MHz from the expected receive carrier frequency of 1 MHz, the oscillator error can be calculated by dividing the value Z by the value Y. In this example, the value Z would be divided by 10 MHz, which is the value of Y in this particular example. The specific frequencies and offsets discussed in the example are intended to illustrate how these techniques can be used to determine an oscillator error for a crystal oscillator, such as oscillator 180, and are not intended to limit the techniques disclosed herein to these specific frequencies and/or offsets.

The calibration unit 195 can be configured to receive the oscillator error from the oscillator error determining unit 190 and to output a signal that can be used to correct frequency inaccuracies of the oscillator 180. The calibration unit 195 can comprise an oscillator drift correction circuit that can be used to bring the oscillator back to the desired predetermined frequency based on the oscillator error. The calibration unit 195 can include circuitry for receiving an output from the oscillator 180, for correcting the frequency of the output based on the oscillator error, and for outputting a corrected frequency to the receive chain 110 and the transmit chain 160 of the wireless computing device 100.

The oscillator error determining unit 190 and the calibration unit 195 can be implemented as hardware, software, or a combination thereof. The oscillator error determining unit 190 and the calibration unit 195 can be implemented as hardware components, such as digital or analog circuits. The functionality of the oscillator error determining unit 190 and the calibration unit 195 can also be implemented by the processor 175 of the baseband processing unit. The oscillator error determining unit 190 and the calibration unit 195 can also be implemented as processor-executable software instructions stored in a non-volatile, computer readable memory of the baseband processing unit 170 or another memory of the wireless computing device 100 which can be executed by the processor 175.

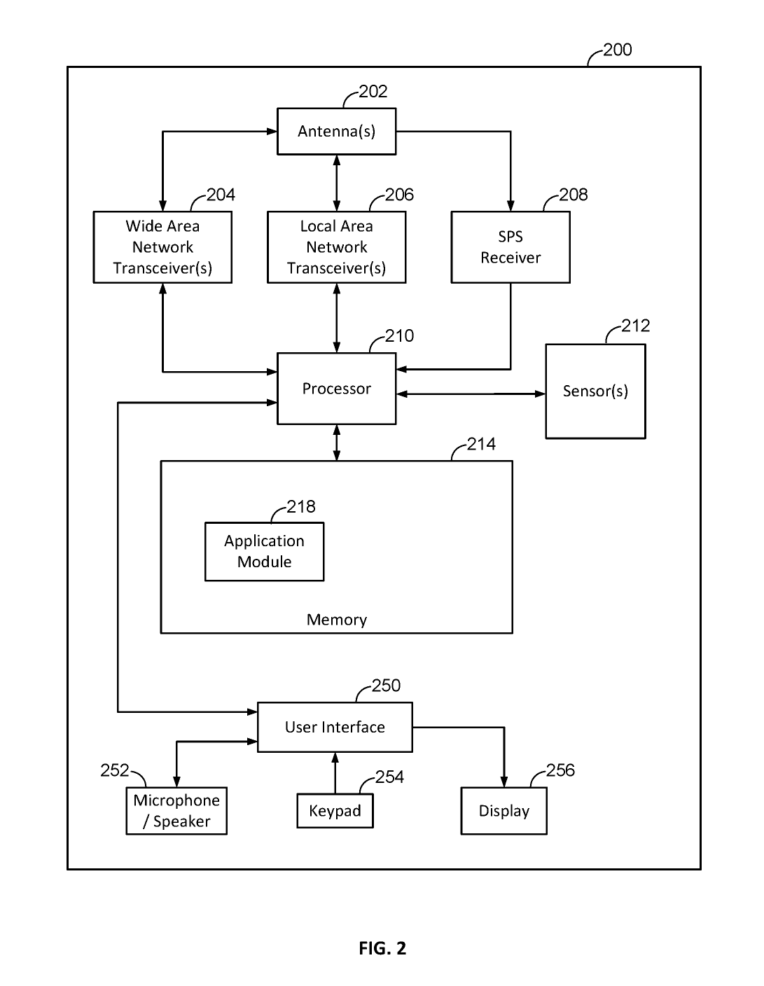

FIG. 2 is a functional block diagram of an example computing device 200 that can be used to implement the wireless computing device 100 illustrated in FIG. 1. FIG. 2 is a schematic diagram illustrating various components of an example computing device 200, which can be similar to or the same as the wireless computing device 100 depicted in FIG. 1. For the sake of simplicity, the various features/components/functions illustrated in the schematic boxes of FIG. 2 are connected together using a common bus to represent that these various features/components/functions are operatively coupled together. Other connections, mechanisms, features, functions, or the like, can be provided and adapted as necessary to operatively couple and configure a portable wireless device. Furthermore, one or more of the features or functions illustrated in the example of FIG. 2 can be further subdivided, or two or more of the features or functions illustrated in FIG. 2 can be combined. Additionally, one or more of the features or functions illustrated in FIG. 2 can be excluded.

As shown, the computing device 200 can include one or more local area network transceivers 206 that can be connected to one or more antennas 202. The one or more local area network transceivers 206 comprise suitable devices, circuits, hardware, and/or software for communicating with and/or detecting signals to/from one or more of the WLAN access points, and/or directly with other wireless devices within a network. In some embodiments, the local area network transceiver(s) 206 can comprise a WiFi (802.11x) communication transceiver suitable for communicating with one or more wireless access points; however, in some embodiments, the local area network transceiver(s) 206 can be configured to communicate with other types of local area networks, personal area networks (e.g., Bluetooth® wireless technology networks), etc. Additionally, any other type of wireless networking technologies can be used, for example, Ultra Wide Band, ZigBee, wireless USB, etc.

The computing device 200 can also include, in some implementations, one or more wide area network transceiver(s) 204 that can be connected to the one or more antennas 202. The wide area network transceiver 204 can comprise suitable devices, circuits, hardware, and/or software for communicating with and/or detecting signals from one or more of, for example, the WWAN access points and/or directly with other wireless devices within a network. In some implementations, the wide area network transceiver(s) 204 can comprise a CDMA communication system suitable for communicating with a CDMA network of wireless base stations. In some implementations, the wireless communication system can comprise other types of cellular telephony networks, such as, for example, TDMA, GSM, WCDMA, LTE etc. Additionally, any other type of wireless networking technologies can be used, including, for example, WiMax (802.16), etc.

In some embodiments, an SPS receiver (also referred to as a global navigation satellite system (GNSS) receiver) 208 can also be included with the computing device 200. The SPS receiver 208 can be connected to the one or more antennas 202 for receiving satellite signals. The SPS receiver 208 can comprise any suitable hardware and/or software for receiving and processing SPS signals. The SPS receiver 208 can request information as appropriate from the other systems, and can perform the computations necessary to determine the position of the computing device 200 using, in part, measurements obtained by any suitable SPS procedure. Some implementations of the computing device 200 may not include an SPS receiver. Furthermore, while the computing device 200 may include an SPS receiver, the computing device 200 may be positioned in a location where the signals from the SPS satellites are obstructed and a time fix from the SPS system cannot be obtained in order to determine and correct for any inaccuracies in the frequency of the crystal oscillator.

As further illustrated in FIG. 2, the example computing device 200 includes one or more sensors 212 coupled to a controller/processor 210. For example, the sensors 212 can include motion sensors to provide relative movement and/or orientation information (which is independent of motion data derived from signals received by the wide area network transceiver(s) 204, the local area network transceiver(s) 206, and/or the SPS receiver 208). By way of example but not limitation, the motion sensors can include an accelerometer, a gyroscope, and a geomagnetic (magnetometer) sensor (e.g., a compass), any of which can be implemented based on micro-electro-mechanical-system (MEMS), or based on some other technology. The motion sensor can be used to identify vibrations and/or other motions that may impact the accuracy of the crystal oscillator of the computing device. The one or more sensors 212 can further include, a thermometer (e.g., a thermistor), an audio sensor (e.g., a microphone) and/or other sensors. The one or more sensors 212 can also include a camera (e.g., a charge-couple device (CCD)-type camera, a CMOS-based image sensor, etc.), which can produce still or moving images (e.g., a video sequence) that can be displayed on a user interface device, such as a display or a screen, and that can be further used to determine an ambient level of illumination and/or information related to colors and existence and levels of UV and/or infra-red illumination. Data collected by the sensors can be used to determine can be used to determine whether one or more threshold conditions for determining an oscillator error has occurred. For example, if the pressure, vibration, humidity, and/or temperature exceed a predetermined threshold associated with one or more of these environmental conditions, the oscillator error associated with the cryptal oscillator can be determined, because these conditions can adversely impact the accuracy of the crystal oscillator.

The processor(s) (also referred to as a controller) 210 can be connected to the local area network transceiver(s) 206, the wide area network transceiver(s) 204, the SPS receiver 208 and the one or more sensors 212. The processor can include one or more microprocessors, microcontrollers, and/or digital signal processors that provide processing functions, as well as other calculation and control functionality. The processor 210 can be coupled to storage media (e.g., memory) 214 for storing data and software instructions for executing programmed functionality within the mobile device. The memory 214 can be on-board the processor 210 (e.g., within the same IC package), and/or the memory can be external memory to the processor and functionally coupled over a data bus.

A number of software modules and data tables can reside in memory 214 and can be utilized by the processor 210 in order to manage both communications with remote devices/nodes, perform positioning determination functionality, and/or perform device control functionality. As illustrated in FIG. 2, in some embodiments, the memory 214 can include an application module 218 which can implement one or more applications. It is to be noted that the functionality of the modules and/or data structures can be combined, separated, and/or be structured in different ways depending upon the implementation of the computing device 200.

The application module 218 can be a process running on the processor 210 of the computing device 200, which can request information from the application module 216 or other data from one of the other modules of the computing device 200. Applications typically run within an upper layer of the software architectures and can be implemented in a rich execution environment of the computing device 200, and can include applications for sensing and/or monitoring of various environmental or other parameters, asset and/or inventory tracking, monitoring of structural integrity, patient monitoring, power usage monitoring, monitoring of air or water quality, and/or numerous other applications in which IoT and/or eMTC devices may be utilized.

The computing device 200 can further include a user interface 250 providing suitable interface systems, such as a microphone/speaker 252, a keypad 254, and a display 256 that allows user interaction with the computing device 200. The microphone/speaker 252 (which can be the same or different from the audio sensor) provides for voice communication services (e.g., using the wide area network transceiver(s) 204 and/or the local area network transceiver(s) 206). The keypad 254 can comprise suitable buttons for user input. The display 256 can include a suitable display, such as, for example, a backlit LCD display, and can further include a touch screen display for additional user input modes.

FIG. 3 is an illustration of an example process for calibrating a crystal oscillator of a wireless device according to the techniques disclosed herein. The process illustrated in FIG. 3 can be implemented using the wireless computing device 100 illustrated in FIG. 1 and/or by the computing device 200 illustrated in FIG. 2. The process illustrated in FIG. 3 can be implemented in a wireless device, such as an IoT or eMTC device to correct inaccuracies in the crystal oscillator. These inaccuracies may be caused by aging of the crystal oscillator, by environmental factors, and/or other influences.

An oscillator error can be determined (stage 305). The oscillator error of the oscillator 180 can be determined by the oscillator error determining unit 190. The oscillator error determining unit 190 can be configured to determine the oscillator error using a technique similar to that illustrated in FIG. 4 in which the receive chain and the transmit chain are tuned to different carrier frequencies and a first tone is transmitted at a frequency that is offset from each of these carrier frequencies and a second tone is received via the receive chain responsive to transmitting the first tone on the transmit chain. This offset enables the oscillator error determining unit 190 to determine the oscillator error. The oscillator error determining unit 190 can be configured to determine the oscillator error in response one or more threshold conditions being satisfied. Example processes for deterring whether such a threshold condition has been satisfied are illustrated in FIG. 5-8.

The crystal oscillator can be calibrated using the oscillator error (stage 310). The calibration unit 195 can be configured to use the oscillator error output by the oscillator error determining unit 190 to calibrate the crystal oscillator. As discussed above, the calibration unit 195 can include an oscillator drift correction circuit that can be used to bring the oscillator back to the desired predetermined frequency based on the oscillator error. The calibration unit 195 can include circuitry for receiving an output from the oscillator 180, for correcting the frequency of the output based on the oscillator error, and for outputting a corrected frequency to the receive chain 110 and the transmit chain 160 of the wireless computing device 100.

FIG. 4 is an illustration of an example process for determining an oscillator error according to the techniques disclosed herein. The process illustrated in FIG. 4 can be used to implement, at least in part, stage 305 of the process illustrated in FIG. 3. The process illustrated in FIG. 4 can also be implemented as a standalone process that is not part of the process of FIG. 3. The process illustrated in FIG. 4 can be implemented by the oscillator error determining unit 190 of the wireless computing device 100 or the computing device 200. The specific frequencies and offsets discussed in the example process are intended to illustrate how these techniques can be used to determine an oscillator error for a crystal oscillator, such as oscillator 180, and are not intended to limit the techniques disclosed herein to these specific frequencies and/or offsets.

A transmit path of the wireless device can be operated at a first carrier frequency (stage 405). The oscillator error determining unit 190 can be configured to configure the transmit chain 160 of the wireless computing device 100 to operate at a predefined carrier frequency. For example, the transmit carrier frequency of the transmit chain 160 can be set to X MHz, where X represents a frequency within a predetermined frequency within a frequency range in which the transmit chain 160 of the wireless computing device 100 is capable of transmitting.

A receive path of the wireless device can be operated at a second carrier frequency offset from the first carrier frequency by a first frequency offset (stage 410). The oscillator error determining unit 190 can be configured to configure the receive chain 110 of the wireless computing device 100 to operate at a predefined carrier frequency. For example, the receive carrier frequency of the receive chain 110 can be set to X+Y MHz, where Y represents a predetermined frequency within the frequency range in which the receive chain 110 is capable of receiving. Y represents a first frequency offset that represents a difference between the transmit carrier frequency and receive carrier frequency. In illustrative example of this concept, Y is equal to 10 MHz.

A first tone can be transmitted using the transmit path at a frequency that is offset from the first carrier frequency by a second frequency offset that is different than the first frequency offset (stage 415). The oscillator error determining unit 190 can be configured to configure the transmit chain 160 to transmit a first tone at 11 MHz on the transmit carrier frequency. The 11 MHz value is selected in this example because this frequency is offset from the transmit carrier frequency by a second frequency offset (1 MHz) that is different than the first frequency offset (10 MHz). Other frequency offsets can be selected so long as the first tone is offset from both the first carrier frequency and the second carrier frequencies.

A second tone can be received via the receive path of the wireless device (stage 420). The oscillator error determining unit 190 can be configured to operate the receive chain 110 in a feedback mode so that a second tone can be received via the receive chain 110 responsive to the first tone being transmitted by the transmit chain 160. The oscillator error determining unit 190 can be configured to down-convert the received signal, which can be performed by oscillator error determining unit 190 or other components of the baseband processing unit 170. The oscillator error determining unit 190 can be configured to down-convert the received signal, which can be performed by oscillator error determining unit 190 or other components of the baseband processing unit 170.

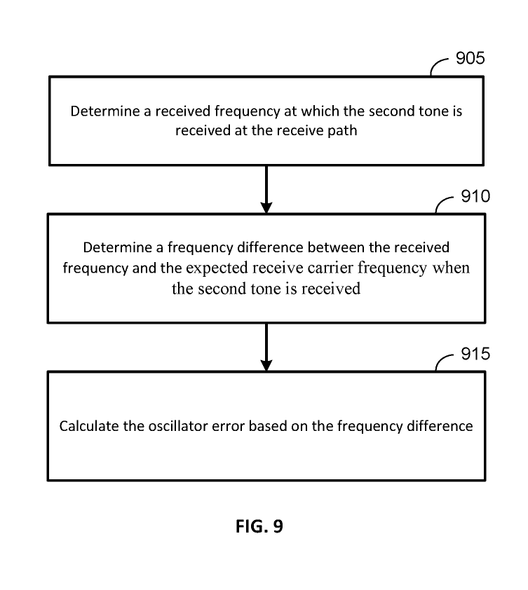

An oscillator error can be determined based on the second tone (stage 425). The oscillator error determining unit 190 can be configured to determine the oscillator error based on the frequency of the tone received and how much that the second tone is shifted from the expected receive carrier frequency when the second tone is received at the receive path. The process illustrated in FIG. 9 provides one example of how the oscillator error may be calculated. Other techniques can also be used to determine the oscillator error based on the frequency offset of the second tone transmitted versus the expected receive carrier frequency when the second tone is received at the receive path.

FIG. 5 is an illustration of an example process for determining an oscillator error according to the techniques disclosed herein. The process illustrated in FIG. 5 can be used to implement, at least in part, stage 305 of the process illustrated in FIG. 3. The process illustrated in FIG. 5 can be used in addition to the process illustrated in FIG. 4 to implement, at least in part, stage 305 of the process illustrated in FIG. 3. The process illustrated in FIG. 5 can be implemented by the oscillator error determining unit 190 of the wireless computing device 100 or the computing device 200.

A determination can be made whether a threshold condition for determining the oscillator error has occurred (stage 505). The threshold condition can be an environmental condition, such as temperature, vibration, humidity, pressure, and/or other environmental conditions that may affect the ability of the crystal oscillator to maintain a desired accuracy, exceeding a predetermined threshold associated with the environmental condition. The threshold condition can be related to the ability of the wireless device to latch onto a network at a predetermined frequency. The threshold condition can be related to an estimated age of the crystal oscillator of the wireless device. In some implementations, more than one threshold condition can be monitored and a determination that the threshold condition has occurred for determining the oscillator error can be made responsive to any of the threshold conditions having been satisfied (or exceeded). In some implementations, more than one threshold condition can be monitored and a determination that the threshold condition has occurred for determining the oscillator error can be made responsive to a minimum number of the threshold conditions having been satisfied FIGS. 6-8 illustrate examples processes for determining whether a threshold condition has occurred. One or more of these example processes may be used to implement, at least in part, stage 505.

The oscillator error can be determined responsive to the threshold condition having occurred (stage 510). The oscillator error determining unit 190 can be configured to determine the oscillator error using the various techniques disclosed herein responsive to the one or more threshold conditions having been satisfied. The oscillator error determining unit 190 can be configured to wait for a predetermined period of time before returning to stage 505 responsive to the threshold condition not having occurred.

FIG. 6 is an illustration of an example process for determining whether a threshold condition for determining an oscillator error has occurred according to the techniques disclosed herein. The process illustrated in FIG. 6 can be used to implement, at least in part, stage 505 of the process illustrated in FIG. 5. The process illustrated in FIG. 6 can be implemented by the oscillator error determining unit 190 of the wireless computing device 100 or the computing device 200.

The wireless device can be waken up from a power saving mode (PSM) (stage 605). While the wireless computing device 100 is the power saving mode, the wireless computing device 100 can be configured to turn off all functionality that is not critical in order to conserve battery power. For example, the wireless computing device 100 can be configured to turn off receiving and transmitting of wireless transmissions while in the PSM. Other functions of the wireless computing device 100 may also turned off while the device in the PSM. The oscillator error determining unit 190 can be configured to activate when the device exits the PSM in order to determine whether the threshold condition for determining the oscillator error has occurred. The wireless computing device 100 can be configured to exit the PSM periodically or may be configured to enter the PSM for a predetermined amount of time in response to a command to enter the PSM.

An attempt to latch onto a network at a predetermined frequency can be made using the receive path of the wireless device (stage 610). Upon exiting the PSM, the processor 175 of the baseband processing unit 170, the CPU of the wireless computing device 100, or another component of the wireless computing device can be configured to cause the wireless computing device 100 to attempt to latch on a network at a predetermined frequency. The receive chain 110 of the wireless computing device 100 can be configured to operate a predetermined carrier frequency and attempt to receive and decode, demodulate, and/or otherwise process signals from the network. The transmit chain 160 can also be configured to operate at the predetermined carrier frequency and can be used to transmit one or more messages to the network in order for the wireless computing device 100 to successfully latch onto the network. The longer that the wireless computing device 100 remains in the PSM, the longer the time intervals between corrections in to the frequency of the oscillator 180. If the frequency error of the oscillator grows too large, the receive chain 110 may not be able to recognize signals from the network or the network may not recognize signals transmitted by the transmit chain 160.

A determination that the threshold condition has occurred can be made responsive to the wireless device being unable to latch onto the network at the predetermined frequency (stage 615). The oscillator error determining unit 190 can be configured to determine monitor the activities of the transceiver 185 to determine whether the wireless computing device 100 has been able to successfully latch onto the network. The oscillator error determining unit 190 can be configured to determine that the threshold condition has occurred responsive to the wireless computing device 100 not having successfully latched onto the network. The oscillator error determining unit 190 can be configured to set a timer of a predetermined length to allow the wireless computing device 100 time to attempt to latch onto the network, and the oscillator error determining unit 190 can be configured to determine that the threshold condition has occurred responsive to the wireless computing device 100 not having successfully latched onto the network prior to the timer elapsing.

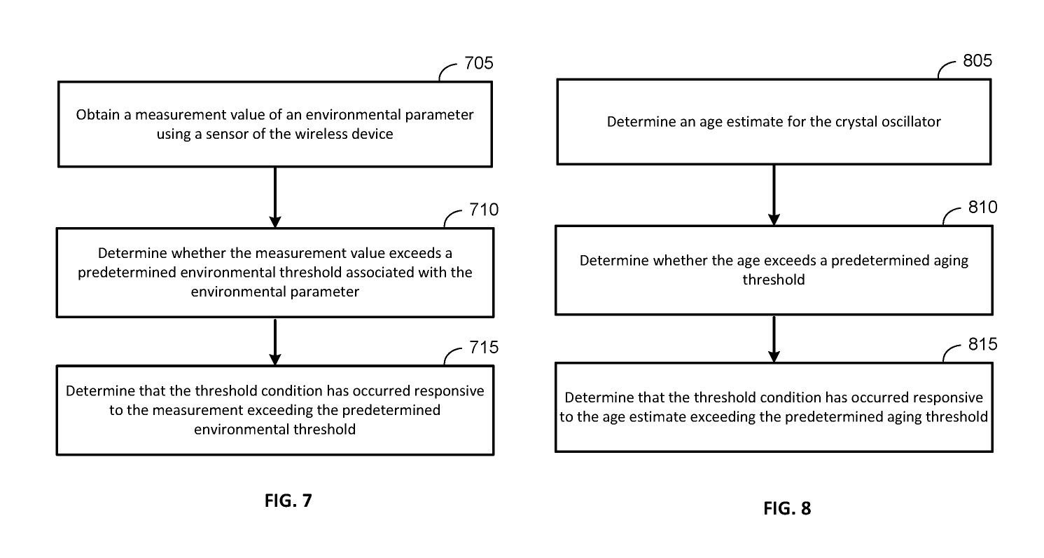

FIG. 7 is an illustration of an example process for determining whether a threshold condition for determining an oscillator error has occurred according to the techniques disclosed herein. The process illustrated in FIG. 7 can be used to implement, at least in part, stage 505 of the process illustrated in FIG. 5. The process illustrated in FIG. 7 can be implemented by the oscillator error determining unit 190 of the wireless computing device 100 or the computing device 200.

A measurement value for an environmental parameter can be obtained using a sensor of the wireless device (stage 705). The wireless computing device 100 can include one or more sensors, such as the sensors 212 discussed above. The oscillator error determining unit 190 can be configured to obtain measurement values from one or more of these sensors. The oscillator error determining unit 190 can be configured to obtain sensor data from environmental sensors that provide data related to temperature, humidity, vibration, pressure, and/or other environmental parameters that can impact the accuracy of the oscillator 180.

A determination can be made whether the measurement value exceeds a predetermined environmental threshold associated with the environmental parameter (stage 710). The oscillator error determining unit 190 can be configured to determine whether one or more of the measurement values obtained from the sensors has exceeded a predetermined environmental threshold. The oscillator error determining unit 190 can be configured to compare data from more than one sensor to a predetermined environmental threshold associated with the environmental parameter measured by each sensor to determine whether any of the measurements exceed a predetermined environmental threshold of the appropriate type. For example, the oscillator error determining unit 190 can be configured to compare sensor data from a motion sensor to a predetermined vibration threshold to determine whether the wireless computing device 100 is being exposed to vibration at a level that can affect the accuracy of the oscillator 180. Similarly, the oscillator error determining unit 190 can be configured to compare sensor data from a pressure sensor to determine whether the wireless computing device 100 is being exposed to a pressure that can affect the accuracy of the oscillator 180. The oscillator error determining unit 190 can be configured to compare sensor data from a temperature sensor to determine whether the wireless computing device 100 is being exposed to a temperature that can affect the accuracy of the oscillator 180. The oscillator error determining unit 190 be configured to receive other types of sensor data in addition to or instead of the examples discussed here. The predetermined threshold information can be determined at least in part based on a cut of the crystal of the oscillator 180. The cut of the crystal can influent the thermal stability, the resistance to vibrations, and other parameters of the oscillator 180. The oscillator error determining unit 190 can be configured with threshold operating parameters appropriate for the cut of the crystal of the oscillator 180.

A determination that the threshold condition has occurred can be made responsive to the measurement exceeding the predetermined environmental threshold (stage 715). The oscillator error determining unit 190 can be configured to determine that the threshold condition for determining the oscillator error has occurred in response to one or more of the measurements exceeding the predetermined thresholds that indicate that the environmental conditions may affect the accuracy of the oscillator 180.

FIG. 8 is an illustration of an example process for determining whether a threshold condition for determining an oscillator error has occurred according to the techniques disclosed herein. The process illustrated in FIG. 8 can be used to implement, at least in part, stage 505 of the process illustrated in FIG. 5. The process illustrated in FIG. 8 can be implemented by the oscillator error determining unit 190 of the wireless computing device 100 or the computing device 200.

An age estimate for the crystal oscillator can be determined (stage 805). The oscillator error determining unit 190 can be configured to access manufacturing date information stored in a memory of the wireless computing device 100. In some devices, the manufacturing date may be estimated from a serial number or model number of the wireless device if manufacturing date information is not otherwise available. The oscillator error determining unit 190 can be configured to perform a lookup of the serial number or model number at a time when the wireless computing device 100 has network access and to store the estimated manufacturing data information in a persistent memory of the wireless computing device 100. The manufacturing date information can be used to estimate an age of the oscillator 180 of the wireless computing device 100.

A determination whether the age estimate exceeds a predetermined aging threshold can be made (stage 810). The oscillator error determining unit 190 can compare the age estimate to a predetermined aging threshold to determine whether the estimate age of the oscillator exceeds the predetermined threshold. The predetermined threshold can be determined based on information on the impact of aging on the crystal of an oscillator such as the oscillator 180. Various factors, including the cut of the crystal, can impact the aging characteristics of the crystal. The oscillator error determining unit 190 can be configured to access a lookup table that includes information such as the cut of the crystal and the age of the crystal to determine when the crystal may have aged enough to impact the accuracy of the oscillator 180 such that the wireless computing device 100 may no longer be able latch onto a network at a predetermined frequency. The predetermined threshold can also be programmed into a memory of the wireless computing device 100 by a manufacturer of the device, and the oscillator error determining unit 190 can be configured to access the predetermined threshold from the memory of the device.

A determination that the threshold condition has occurred can be made responsive to the age estimate exceeding the predetermined aging threshold (stage 815). The oscillator error determining unit 190 can be configured to determine that the threshold condition for determining the oscillator error has occurred in response to the estimated age of the crystal exceeding the predetermined threshold (or being less than the threshold when the newness of the crystal is taken into account.

FIG. 9 is an illustration of an example process for determining an oscillator error has occurred according to the techniques disclosed herein. The process illustrated in FIG. 9 can be used to implement, at least in part, stage 425 of the process illustrated in FIG. 4. The process illustrated in FIG. 9 can be implemented by the oscillator error determining unit 190 of the wireless computing device 100 or the computing device 200. The specific frequencies and offsets discussed in the example process are intended to illustrate how these techniques can be used to determine an oscillator error for a crystal oscillator, such as oscillator 180, and are not intended to limit the techniques disclosed herein to these specific frequencies and/or offsets.

The oscillator error can be expressed as Z/Y, where Z represents the frequency at which a first tone transmitted by the transmit chain is received by the receive chain as a second tone, where the transmit chain is configured to operate at X MHz, where X represents a frequency within a predetermined frequency within a frequency range in which the transmit chain 160 of the wireless computing device 100 is capable of transmitting, where the receive chain is configured to operate at X+Y MHz, where X+Y represents a predetermined frequency within the frequency range in which the receive chain 110 is capable of receiving, and where Y represents a first frequency offset that represents a difference between the transmit carrier frequency and receive carrier frequency, where the first tone is transmitted by the receive chain at a frequency T that is offset from the frequency X by a second frequency offset that is different than the first frequency offset, and where Z represents a difference between the actual received frequency F of the second tone received at the receive chain and the expected receive carrier frequency when the second tone is received at the receive path E, wherein E=T−Y.

A frequency at which the second tone is received at the receive path can be determined (stage 905). The first tone can be transmitted by the transmit chain 160 at a predetermined frequency that is offset from the receive carrier frequency of the receive chain 110 of the wireless computing device 100. For example, the oscillator error determining unit 190 can be configured to set the receive carrier frequency of the receive chain 110 to be 10 MHz (a first frequency offset) from the transmit carrier frequency of the transmit chain 160. The first tone can be transmitted at a frequency that is offset from both the transmit and receive carrier frequencies. For example, the first tone may be transmitted at 11 MHz which is offset by 1 MHz from the receive carrier frequency. The frequency of the first tone should be offset from the transmit carrier frequency by a different frequency offset than the frequency offset of the first tone from the receive carrier frequency. The carrier frequencies of the transmit and receive chains are tuned to different frequencies so that the error introduced by the oscillator drift will be different for the send and receive chains, and the delta between these two errors can be used to estimate the frequency error.

A frequency difference between the received frequency and an expected receive frequency of the second tone can be determined (stage 910). Continuing with the example discussed above with respect to stage 905, the first tone was transmitted at 11 MHz by the transmit chain and the carrier frequency of the receive chain is offset from that of the receive chain by 10 MHz. Therefore, if there was no frequency drift by the oscillator 180, the expected receive carrier frequency when the second tone is received at the receive path is expected to be at 1 MHz, because the carrier frequency of the receive chain is offset by 10 MHz from the carrier frequency of the transmit chain in this example and the transmit chain transmitted the first tone at 11 MHz. Frequency drift by the oscillator 180 will cause the receive frequency to vary from this expected value. A difference between the received frequency and the transmit frequency can be determined by subtracting the received frequency from the expected receive carrier frequency when the second tone is received at the receive path.

The oscillator error can be determined based on the frequency difference (stage 915). The oscillator error determining unit 190 can be configured to divide the frequency difference by the first frequency offset to determine the oscillator error. Continuing with the example discussed above with respect to stage 905 and stage 910, frequency difference can be divided by 10, because the first frequency offset is 10 MHz to determine the value of the oscillator error. The specific frequencies and offsets used in the example discussed with respect to FIG. 9 are meant to illustrate the concepts discussed herein and are not intended to limit the scope of these techniques to the specific frequencies and offsets used to illustrate these concepts.

The methodologies described herein may be implemented by various means depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media. Tangible media include one or more physical articles of machine readable media, such as random access memory, magnetic storage, optical storage media, and so on.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media. Such media also provide examples of non-transitory media, which can be machine readable, and wherein computers are an example of a machine that can read from such non-transitory media.

The generic principles discussed herein may be applied to other implementations without departing from the spirit or scope of the disclosure or claims.

What is claimed is:

1. A method for calibrating a crystal oscillator of a wireless device, the method comprising:
operating a transmit path of the wireless device at a first carrier frequency;
operating a receive path of the wireless device at a second carrier frequency, the second carrier frequency being offset from the first carrier frequency by a first frequency offset;
transmitting a first tone via the transmit path at a third carrier frequency, wherein the third carrier frequency is offset from the first carrier frequency by a second frequency offset, and wherein the second frequency offset is different than the first frequency offset;
receiving a second tone via the receive path; and
determining an oscillator error based on the second tone.

2. The method of claim 1, wherein the first frequency offset is 10 MHz and the second frequency offset is 11 MHz.

3. The method of claim 1, wherein determining the oscillator error comprises:
determining a received frequency at which the second tone is received at the receive path;
determining a frequency difference between the received frequency and an expected receive carrier frequency when the second tone is received at the receive path; and
calculating the oscillator error based on the frequency difference.

4. The method of claim 3, wherein calculating the oscillator error based on the frequency difference includes dividing the frequency difference by 10.

5. The method of claim 1, further comprising:
determining whether a threshold condition for determining the oscillator error has occurred.

6. The method of claim 5, wherein determining whether the threshold condition has been satisfied further comprises:
waking the wireless device from a power save mode (PSM);
attempting to latch on to a network at a predetermined frequency using the receive path of the wireless device; and
determining that the threshold condition has occurred responsive to being unable to latch onto the network at the predetermined frequency.

7. The method of claim 5, wherein determining whether the threshold condition has been satisfied further comprises:
obtaining a measurement of an environmental parameter using a sensor of the wireless device;
determining whether the measurement exceeds a predetermined environmental threshold associated with the environmental parameter; and
determining that the threshold condition has occurred responsive to the measurement exceeding the predetermined environmental threshold.

8. The method of claim 5, wherein determining whether the threshold condition has been satisfied further comprises:
determining an age estimate for the crystal oscillator;
determining whether the age estimate exceeds a predetermined aging threshold; and
determining that the threshold condition has occurred responsive to the age estimate exceeding the predetermined aging threshold.

9. The method of claim 1, further comprising calibrating the crystal oscillator based on the oscillator error.

10. An apparatus comprising:
an oscillator error determining unit configured to determine an oscillator error of a crystal oscillator of a wireless device, the oscillator error determining unit being configured to
operate a transmit path of the wireless device at a first carrier frequency;
operate a receive path of the wireless device at a second carrier frequency, the second carrier frequency being offset from the first carrier frequency by a first frequency offset;
transmit a first tone via the transmit path at a third carrier frequency, wherein the third carrier frequency is offset from the first carrier frequency by a second frequency offset, and wherein the second frequency offset is different than the first frequency offset;
receive a second tone via the receive path; and
determine the oscillator error based on the second tone.

11. The apparatus of claim 10, wherein the first frequency offset is 10 MHz and the second frequency offset is 11 MHz.

12. The apparatus of claim 10, wherein the oscillator error determining unit is configured to:
determine a received frequency at which the second tone is received at the receive path;
determine a frequency difference between the received frequency and an expected receive carrier frequency when the second tone is received at the receive path; and
calculate the oscillator error based on the frequency difference.

13. The apparatus of claim 12, wherein the oscillator error determining unit is configured to calculate the oscillator error based on the frequency difference includes dividing the frequency difference by 10.

14. The apparatus of claim 10, wherein the oscillator error determining unit is configured to:
determine whether a threshold condition for determining the oscillator error has occurred.

15. The apparatus of claim 14, wherein the oscillator error determining unit is configured to:
wake the wireless device from a power save mode (PSM);
attempt to latch on to a network at a predetermined frequency using the receive path of the wireless device; and
determine that the threshold condition has occurred responsive to being unable to latch onto the network at the predetermined frequency.

16. The apparatus of claim 14, wherein the oscillator error determining unit is configured to:
obtain a measurement of an environmental parameter using a sensor of the wireless device;
determine whether the measurement exceeds a predetermined environmental threshold associated with the environmental parameter; and
determine that the threshold condition has occurred responsive to the measurement exceeding the predetermined environmental threshold.

17. The apparatus of claim 14, wherein the oscillator error determining unit is configured to:
determine an age estimate for the crystal oscillator;
determine whether the age estimate exceeds a predetermined aging threshold; and
determine that the threshold condition has occurred responsive to the age estimate exceeding the predetermined aging threshold.

18. An apparatus comprising:
means for operating a transmit path of a wireless device at a first carrier frequency;
means for operating a receive path of the wireless device at a second carrier frequency, the second carrier frequency being offset from the first carrier frequency by a first frequency offset;
means for transmitting a first tone via the transmit path at a third carrier frequency, wherein the third carrier frequency is offset from the first carrier frequency by a second frequency offset, and wherein the second frequency offset is different than the first frequency offset;
means for receiving a second tone via the receive path; and
means for determining an oscillator error of a crystal oscillator of the wireless device based on the second tone.

19. The apparatus of claim 18, wherein the first frequency offset is 10 MHz and the second frequency offset is 11 MHz.

20. The apparatus of claim 18, wherein the means for determining the oscillator error comprises:
means for determining a received frequency at which the second tone is received at the receive path;
means for determining a frequency difference between the received frequency and an expected receive carrier frequency when the second tone is received at the receive path; and
means for calculating the oscillator error based on the frequency difference.

21. The apparatus of claim 18, further comprising:
means for determining whether a threshold condition for determining the oscillator error has occurred.

22. The apparatus of claim 21, wherein the means for determining whether the threshold condition has been satisfied further comprises:
means for waking the wireless device from a power save mode (PSM);
means for attempting to latch on to a network at a predetermined frequency using the receive path of the wireless device; and
means for determining that the threshold condition has occurred responsive to being unable to latch onto the network at the predetermined frequency.

23. The apparatus of claim 21, wherein the means for determining whether the threshold condition has been satisfied further comprises:
means for obtaining a measurement of an environmental parameter using a sensor of the wireless device;
means for determining whether the measurement exceeds a predetermined environmental threshold associated with the environmental parameter; and
means for determining that the threshold condition has occurred responsive to the measurement exceeding the predetermined environmental threshold.

24. The apparatus of claim 21, wherein the means for determining whether the threshold condition has been satisfied further comprises:
means for determining an age estimate for the crystal oscillator;
means for determining whether the age estimate exceeds a predetermined aging threshold; and
means for determining that the threshold condition has occurred responsive to the age estimate exceeding the predetermined aging threshold.

25. A non-transitory, computer-readable medium, having stored thereon computer-readable instructions for calibrating a crystal oscillator of a wireless computing device, comprising instructions configured to cause the wireless computing device to:
operate a transmit path of the wireless computing device at a first carrier frequency;
operate a receive path of the wireless computing device at a second carrier frequency, the second carrier frequency being offset from the first carrier frequency by a first frequency offset;
transmit a tone via the transmit path at a third carrier frequency, wherein the third carrier frequency being offset from the first carrier frequency by a second frequency offset and wherein the second frequency offset is different than the first frequency offset;
receive a second tone via the receive path; and
determine an oscillator error based on the second tone.

26. The non-transitory, computer-readable medium of claim 25, wherein the first frequency offset is 10 MHz and the second frequency offset is 11 MHz.

27. The non-transitory, computer-readable medium of claim 25, wherein the instructions configured to cause the wireless computing device to determine the oscillator error further comprise instructions configured to cause the wireless computing device to:
determine a received frequency at which the second tone is received at the receive path;
determine a frequency difference between the received frequency and an expected receive carrier frequency when the second tone is received at the receive path; and
calculate the oscillator error based on the frequency difference.

28. The non-transitory, computer-readable medium of claim 25, further comprising instructions configured to cause the wireless computing device to:
determine whether a threshold condition for determining the oscillator error has occurred.

29. The non-transitory, computer-readable medium of claim 28, wherein the instructions configured to cause the wireless computing device to determine whether the threshold condition has been satisfied further comprise instructions configured to cause the wireless computing device to:
wake the wireless computing device from a power save mode (PSM);
attempt to latch on to a network at a predetermined frequency using the receive path of the wireless computing device; and
determine that the threshold condition has occurred responsive to being unable to latch onto the network at the predetermined frequency.

30. The non-transitory, computer-readable medium of claim 28, wherein the instructions configured to cause the wireless computing device to determine whether the threshold condition has been satisfied further comprise instructions configured to cause the wireless computing device to:
obtain a measurement of an environmental parameter using a sensor of the wireless computing device;
determine whether the measurement exceeds a predetermined environmental threshold associated with the environmental parameter; and
determine that the threshold condition has occurred responsive to the measurement exceeding the predetermined environmental threshold.
